(19) United States
(12) Patent Application Publication
(10) Pub. No.: US 2020/0194332 A1
(43) Pub. Date: Jun. 18, 2020

(54) MULTI-PIECE HEAT SPREADER FOR MULTI-CHIP PACKAGE

(71) Applicant: Intel Corporation, Santa Clara, CA (US)

(72) Inventors: Sandeep Ahuja, Portland, OR (US); Je-young Chang, Phoenix, AZ (US); Phil Geng, Portland, OR (US); Shrenik Kothari, Chandler, AZ (US); Francisco Gabriel Lozano Sanchez, Tlajomulco de Zuniga (MX)

(21) Appl. No.: 16/642,617

(22) PCT Filed: Sep. 28, 2017
(86) PCT No.: PCT/US2017/054058

§ 371 Date: Feb. 27, 2020

(51) Int. Cl. H01L 23/367; H01L 23/31; H01L 21/48; H01L 21/56

(52) U.S. Cl. CPC H01L 23/367; H01L 21/56; H01L 21/4882; H01L 23/3142

(57) ABSTRACT

A microelectronic device may include a substrate, a first component, a second component, a slug, a heat spreader, and a heatsink. The substrate may include a plurality of electrically conductive elements. The first component may be coupled to the substrate. The second component may be coupled to the substrate. The slug may be thermally coupled to the second component. The heat spreader may be in contact with the substrate, where the heat spreader may be thermally coupled to the first component. The heatsink may be thermally coupled to the heat spreader and the slug.

### TECHNICAL FIELD

Embodiments described herein generally relate to thermally conductive components for microelectronic devices and systems.

### BACKGROUND

Processors, chips, and components of microelectronic devices typically produce heat in use. This heat must be rejected to another environment to maintain an acceptable operating temperature of the microelectronic device. In many cases, the microelectronic device includes a conductive surface that is coupleable to a device to which heat may be transferred, such as a heatsink. In many cases, a layer of thermal interface material (TIM) is disposed between the heatsink and the microelectronic device to increase thermal coupling between the heatsink and the microelectronic device. However, some applications may include more than one component or chip.

### BRIEF DESCRIPTION OF THE DRAWINGS

FIG. 1 illustrates a plan view of a microelectronic assembly, in accordance with at least one example of the present disclosure.

FIG. 2A illustrates a cross-sectional elevation view of a microelectronic assembly, in accordance with at least one example of the present disclosure.

FIG. 2B illustrates a focused cross-sectional elevation view of a microelectronic assembly, in accordance with at least one example of the present disclosure.

FIG. 3 illustrates a plan view of another microelectronic assembly, in accordance with at least one example of the present disclosure.

FIG. 4 illustrates a plan view of another microelectronic assembly, in accordance with at least one example of the present disclosure.

FIG. 5 illustrates a plan view of yet another microelectronic assembly, in accordance with at least one example of the present disclosure.

FIG. 6 illustrates a plan view of yet another microelectronic assembly, in accordance with at least one example of the present disclosure.

FIG. 7 illustrates a flow chart of a method, in accordance with at least one example of the present disclosure.

FIG. 8 illustrates a system level diagram, in accordance with at least one example of the present disclosure.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

Some microelectronic devices, such as packages, may include multiple components arranged on a common substrate. Often, individual components may receive a layer of TIM and an integrated heat spreader (IHS) may be placed in contact with the TIM layer covering each component. A heatsink may then be thermally coupled to the IHS, with a second TIM layer disposed between the heatsink and the IHS. The heatsink may then, in operation, reject heat from each component.

However, some packages of components may include components having different heights from the substrate. While it is possible to account for height differences between components with steps (or thickness variations) in the IHS, it is difficult to account for stack height tolerances that result in varying die stack heights from one part to other with a single IHS. Because a substantially planar IHS is typically thermally coupled to each component of the same height, gaps of varying heights may be created between the IHS and components. The varying gaps are made up by varying a thickness or height of a layer of TIM between each component and the IHS. This may cause some components to have a TIM layer thicker than desired for effective heat transfer, which may cause components to operate at temperatures outside of a desired range, reducing efficiency of the components. Slugs (or individual heat spreaders for each component) have been introduced as a solution to this problem; however, use of a single slug for each component may significantly increase bill of material cost over the use of a single IHS.

The present disclosure includes, in some examples, devices to increase thermal performance while reducing bill of material cost by including slugs thermally coupled to some components of a package while thermally coupling other components directly to the IHS. This allows for individual TIM layers to be applied to each component, allowing for thickness or height control of the individual TIM layers, increasing thermal efficiency, while avoiding individual slugs for each component, keeping bill of material cost down. The present disclosure further includes systems and methods that, in some cases, include a single slug may be used for more than one component, further reducing bill of material cost.

In one example, a microelectronic device may include a substrate, a first component, a second component, a slug, a heat spreader, and a heatsink. The substrate may include a plurality of electrically conductive elements. The first component may be coupled to the substrate. The second component may be coupled to the substrate. The slug may be thermally coupled to the second component. The heat spreader may be in contact with the substrate, where the heat spreader may be thermally coupled to the first component. The heatsink may be thermally coupled to the heat spreader and the slug.

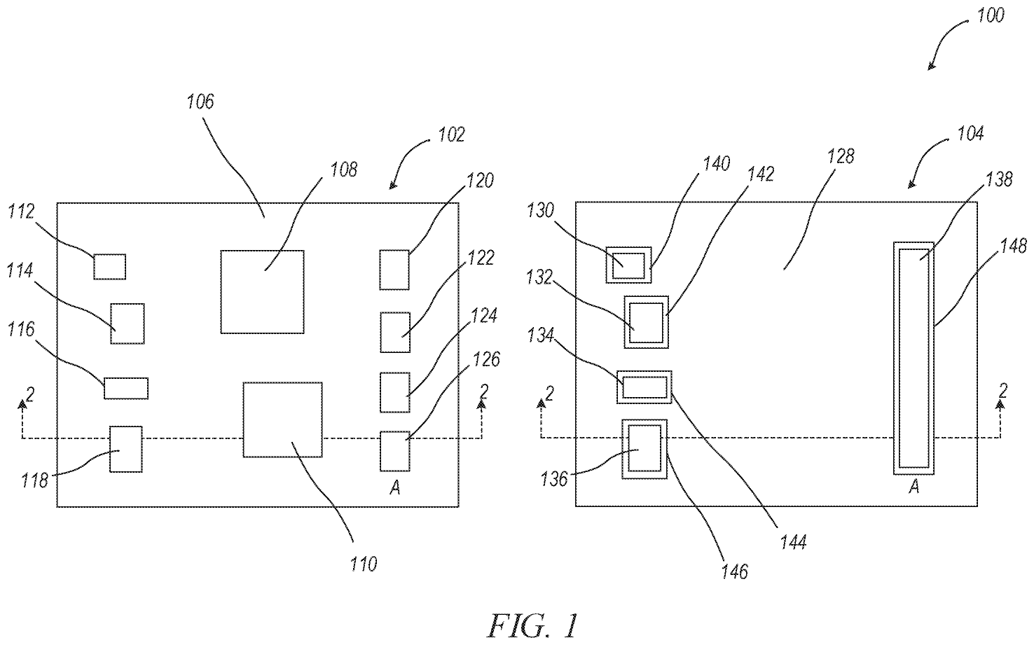

FIG. 1 illustrates a plan view of a microelectronic assembly 100, in accordance with at least one example of the present disclosure. Microelectronic assembly 100 may include package 102 and thermal assembly 104. Package 102 may include substrate 106, and components 108, 110, 112, 114, 116, 118, 120, 122, 124, and 126. Thermal assembly 104 may include heat spreader 128 and slugs 130, 132, 134, 136, and 138. Heat spreader 128 may include openings 140, 142, 144, 146, and 148.

In some examples, package 102 may be a microelectronic device board, such as an integrated circuit board, including a board or substrate and components supported thereby. Substrate 106 may be a microelectronic device substrate, such as an integrated circuit board, including transistors and circuits of any of multiple forms known in the industry, providing conductive structures, physical support for components, and electrical contacts to distribute signals. Such components of substrate 106 are well known to persons skilled in the art and are therefore not discussed in detail herein. In some examples, substrate 106 may connect to a power supply, volatile memory, and non-volatile memory in a case or enclosure as described in further detail below.

Each of components 108-126 may be any one of active and passive electronic device components, such as dies, transistors, memories, capacitors, resistors, optoelectronic devices, switches, interconnects, and any other electronic device component. In some examples, components 108-126 may be dies, such as central processing units (CPUs), graphics processing units (GPUs), 3D stacked or non-stacked memory, field programmable gate array (FPGA), modems, other integrated packages (IPs), and the like. Each of components 108-126 may be coupled or secured to substrate 106. In some examples, each of components 108-126 may be in communication (through electric or other means) with substrate 106.

Thermal assembly 104 may be an assembly of components configured to interact thermally with a package, such as package 102, to transfer heat therefrom to another environment. Though not shown in FIG. 1, thermal assembly 104 may include a heatsink configured to thermally couple with heat spreader 128 and slugs 140-148.

Slugs 130, 132, 134, 136, and 138 may be thermally conductive individual heat spreaders configured to thermally couple to a heatsink or heat spreader and to any of components 108-126. Slugs 130, 132, 134, 136, and 138 may be comprised of any thermally conductive material, such as copper, aluminum, gold, silver, vapor chamber, graphite compound, combinations and alloys thereof, and the like. In one example, each of slugs 130-138 may be thermally coupled to one or more component. For example, slug 130 may be thermally coupled to component 112; slug 132 may be thermally coupled to component 114; slug 134 may be thermally coupled to component 116; slug 136 may be thermally coupled to component 118; and, slug 138 may be thermally coupled to components 120, 122, 124, and 126.

Heat spreader 128 may be a thermally conductive frame configured to thermally couple to a heatsink, to slugs 130-138, and to any of components 108-126. In one example, heat spreader 128 may be thermally coupled to components 108 and 110. Heat spreader 128 may be comprised of any thermally conductive material, such as copper, aluminum, gold, silver, vapor chamber, graphite compound, copper block integrated with microchannels, and the like. Heat spreader may be sized to thermally couple to one or more of the components described above as well as to a full surface area of the heatsink to spread or distribute thermal load from components over substantially all of a surface of the heatsink.

Heat spreader 128 may include openings 140, 142, 144, 146, and 148, which may each be sized to receive one or more of slugs 130, 132, 134, 136, and 138 therein. In one example: slug 130 may be disposed or located in opening 140; slug 132 may be located in opening 142; slug 134 may be located in opening 144; slug 136 may be located in opening 146; and, slug 138 may be located in opening 148. Heat spreader 128 may also be in contact with and supported by substrate 106. In some examples, heat spreader 128 may be secured to substrate 106 using sealant, epoxy, solder, or fasteners (such as screws or rivets).

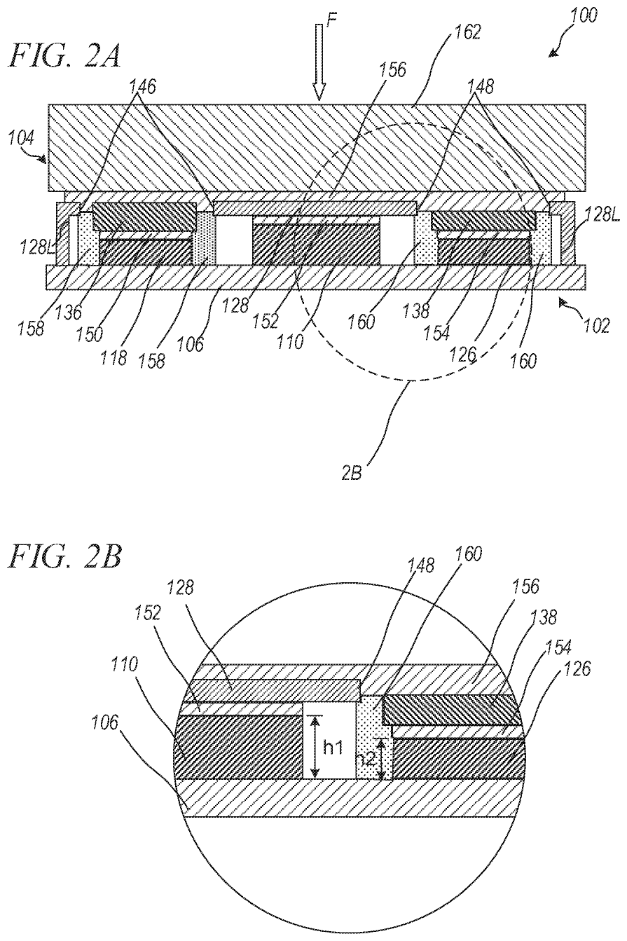

As shown and described with respect to FIGS. 2A and 2B below (not shown in FIG. 1), each of slugs 130, 132, 134, 136, and 138 may be thermally coupled to one of components 112-126 (for example with a TIM layer disposed between each slug and each component). In one example, slug 130 may be thermally coupled to component 112; slug 132 may be thermally coupled to component 114; slung 134 may be thermally coupled to component 116; slug 136 may be thermally coupled to component 118; and, slug 138 may be thermally coupled to each of components 120, 122, 124, and 126. Also, components 108 and 110 may be thermally coupled to heat spreader 128.

Interaction between and operation of the components of FIG. 1 are discussed below in further detail with respect to FIGS. 2A, 29, and 6.

FIG. 2A illustrates a cross-sectional elevation view of microelectronic assembly 100, in accordance with at least one example of the present disclosure. FIG. 2B illustrates a focused cross-sectional elevation view of microelectronic assembly 100, in accordance with at least one example of the present disclosure. FIGS. 2A and 2B are discussed concurrently.

Microelectronic assembly 100 may include package 102 and thermal assembly 104, which may be consistent with FIG. 1 discussed above; however, FIGS. 2A and 2B only discuss a portion of microelectronic assembly 100 of FIG. 1. Package 102 may include substrate 106, and components, 110, 118, and 126. Thermal assembly 104 may include heat spreader 128 and slugs 136 and 138. Heat spreader 128 may include openings 146 and 148. Microelectronic assembly 100 may also include TIM layers 150, 152, 154, and 156, sealants 158 and 160, and heatsink 162. Also shown in FIG. 2A is force F and also shown in FIG. 2B are height h1 and height h2.

TIM layers 150, 152, 154, and 156 may each be thermal interface material, such as thermal paste, thermal compound, indium, metallic alloy, or thermal grease comprised of a thermally conductive compound. In some examples, TIM layers 150-156 may include materials such as diamond, boron, aluminum, alumina, silver, zinc, metallic alloy, carbon compounds, and copper. Each of TIM layers 150-156 may be configured to increase a contact area between adjacent components to increase thermal transfer efficiency therebetween. As shown in FIG. 2A: TIM layer 150 may be disposed between component 118 and slug 136 to thermally couple component 118 to slug 136; TIM layer 152 may be disposed between component 110 and heat spreader 128 to thermally couple component 110 to heat spreader 128; TIM layer 154 may be disposed between component 126 and slug 138 to thermally couple component 126 to slug 128; and, TIM layer 156 may be disposed between heatsink 162 and each of heat spreader 128, slug 136, slug 138, and sealants 158 and 160 to thermally couple heatsink 162 to each of spreader 128, slug 136, slug 138, and sealants 158 and 160.

Sealants 158 and 160 may be structural and/or thermal layers, comprised of materials such as a polymer resin or polyimide, in some examples, and may include conductive materials in some other examples. In one example, sealant 158 may enclose component 118, TIM layer 150, and a portion of slug 136, such that a top of slug 136 is still exposed. Similarly, sealant 160 may enclose component 126, TIM layer 154, and a portion of slug 138, such that a top of slug 138 is still exposed.

In some examples, sealants 158 and 160 may provide structural support for the components surrounded thereby. In some examples, each of sealants 158 and 160 may be comprised of compounds selected for particular rigidity or flexibility such that a desired structural relationship between each of sealants 158 and 160 may be selected based on the application thereof. Similarly, each of sealants 158 and 160 may be comprised of compounds selected to thermally couple the components in contact with sealants 158 and 160 or to thermally isolate the components in contact with sealants 158 and 160, as discussed further below.

Heatsink 162 may be a thermally conductive heat exchanger configured to thermally couple to one or more of heat spreader 128 and slugs 130-138. In some examples, heatsink 162 may be a passively cooled or actively cooled (coupled to a fan or pump) heat exchanger configured to exchange heat with a surrounding or connected environment. Heatsink 162 may be comprised of any thermally conductive material, such as copper, aluminum, gold, silver, and the like. In other examples, heatsink 162 may be cooled by a single phase liquid (such as water, an antifreeze-water mixture, or liquid metallics) or a two-phase refrigerant (such as R-134A, alcohol, ammonia, or nitrogen). Heatsink 162 may be further coupled to a fan, pump, or additional heat exchanger for transfer of heat from heatsink 162.

In some examples, the components of microelectronic system 100 may be connected as described above and as shown in FIGS. 2A and 2B. In operation of some of these examples, each of components 110, 118, and 126 may produce a heat load to be transferred away from these components and rejected by heatsink 162, allowing each of components 110, 118, and 126 to maintain working temperatures in an operational range.

More specifically, component 118 may transfer heat through TIM layer 150 to slug 136. Slug 136 may distribute and transfer heat to heatsink 162 through TIM layer 156. Similarly, component 126 may transfer heat through TIM layer 154 to slug 138 and slug 138 may transfer heat to heatsink 162 through TIM layer 156. Component 110 may transfer heat through TIM layer 152 to heat spreader 128, which may distribute the heat throughout the surface of heat spreader 128 for transfer of heat to heatsink 162 through TIM layer 156. Heatsink 162 may then reject the heat to air, liquid, refrigerant, another heat exchanger, or other device or means.

In some examples, components may have different heights from substrate 106. For example, component 110 may have a height h1 that is larger or taller than a height h2 of component 126 from substrate 106. In some solutions in the prior art, this height difference is compensated for by using TIM layers having varying thicknesses to interact with the thermal spreader. However, increasing a thickness of the TIM layer may decrease thermal transfer efficiency, causing higher operating temperatures of the components receiving thicker TIM layers. Therefore, individual heat spreaders or slugs may be used to optimize TIM layer thickness. This design, while efficient, may increase the BOM cost by requiring slugs for each component.

One solution to these problems is to design heat spreader 128 to directly contact one or more component having heights larger than other components and to include openings in heat spreader 128, to receive slugs for components having smaller heights. For example, as shown in FIG. 2B, height h2 of component 126 is lower than height h1 of component 110. Heat spreader 128 may be sized such that component 110 may be thermally coupled to heat spreader 128 via TIM layer 152 and heat spreader 128 may be designed to include opening 148 to receive slug 154 therein. This allows for use of TIM layer 152 to be sized for thermal performance of component 110 and TIM layer 154 to be sized for thermal performance of component 126, increasing efficiency and performance of components 110 and 126, without the need for an individual heat spreader or slug for component 110.

In some examples, a height of the slug and the heat spreader may be matched so that TIM layer 156 is substantially uniform across all of the slugs and heat spreader 128 as shown with respect to slug 136 and heat spreader 128. In other examples, slugs may have a height lower than heat spreader 128, as shown with respect to slug 138 and heat spreader 128. In some examples, slugs of different heights that represent a range of height difference between the die surface and the IHS frame top surface can be pre-manufactured. In these examples, a slug of a given thickness that sits just below the IHS top frame surface can be installed to maximize thermal performance of the assembly. In yet other examples, slugs may have a height higher than heat spreader 128.

In some examples, sealants 158 and 160 may have properties that are selected based on requirements of microelectronic system 100. For example, it may be desirable to thermally couple a component to its slug and to the heat spreader, such as when a component has a relatively high thermal output and transfer to as many components is possible may reduce operating temperatures of the component. As shown in FIG. 2B, sealant 160 couples component 126 to TIM layer 154, slug 138, heat spreader 128 and TIM layer 156. In some examples, sealant 160 may be thermally conductive to thermally couple all of component 126, TIM layer 154, slug 138, heat spreader 128 and TIM layer 156.

In other examples, it may be desirable to thermally isolate a component and its slug from the heat spreader, such as when a component is sensitive to a thermal output of a nearby component that is coupled to the heat spreader. For example, sealant 160 may insulate component 126, TIM layer 154, and slug 138, from heat spreader 128.

In some examples, sealants 158 and 160 may be selected for structural properties. For example, sealant 160 may be selected to be either a rigid sealant or a flexible sealant depending on the operating conditions of the components of microelectronic system, such as anticipated load (force F) and anticipated thermally induced expansion and contraction forces.

In some examples, components may be sensitive to forces. For example, component 126 may be sensitive to force F, which may be a force applied to heat spreader 128 by, for example, the mass of heatsink 162 or a force provided by means of attachment of heatsink 162 and and/or heat spreader 128 to substrate 106. In these examples, heat spreader 128 may transfer force F through legs 128L to substrate 106 such that force F is not transferred to component 126. In these examples, sealant 160 may be selective to transfer force to substrate 106 to minimize transfer of force to component 126.

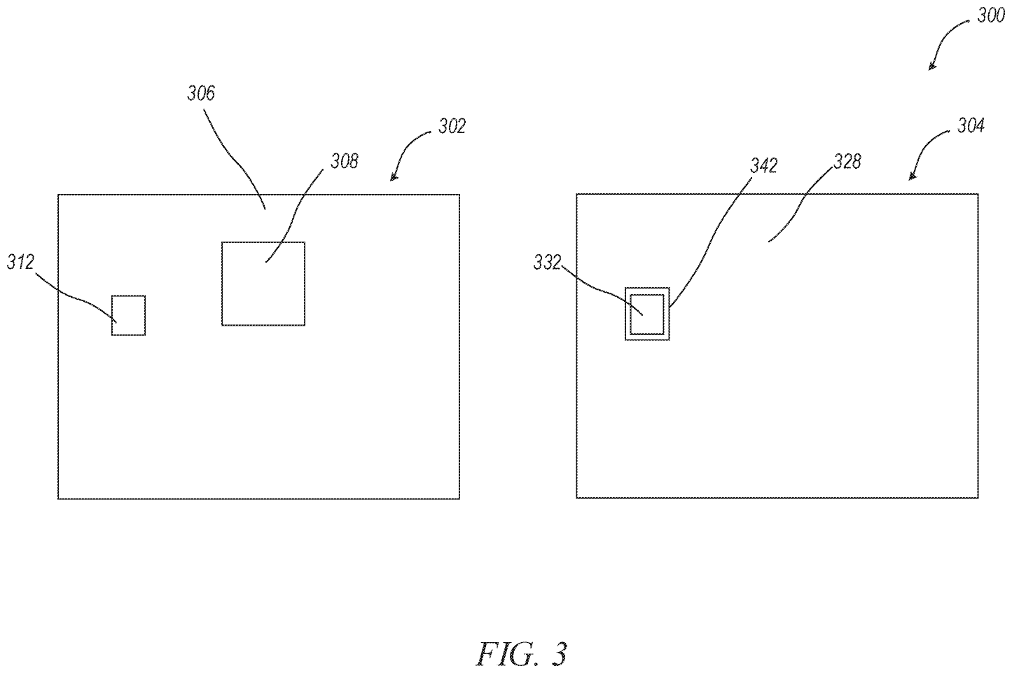

FIG. 3 illustrates a plan view microelectronic assembly 300, in accordance with at least one example of the present disclosure. Microelectronic assembly 300 includes package 302 and thermal assembly 304. Package 302 may include substrate 306, component 308, and component 312. Thermal assembly may include heat spreader 328 and slug 332. Heat spreader 328 may include opening 342.

Microelectronic assembly 300 may be similar to microelectronic assembly 100 discussed above with respect to FIGS. 1-2B, except FIG. 3 shows how microelectronic assembly 300 may include only a single slug, slug 332, which may be thermally coupled to component 312, while component 308 may be thermally coupled to heat spreader 328.

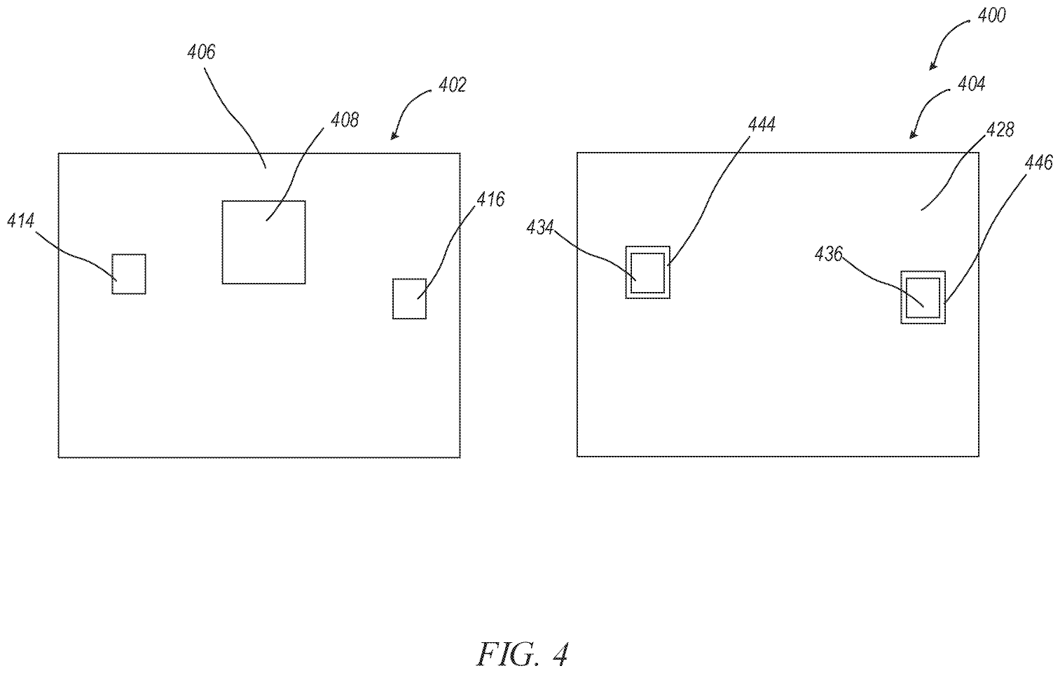

FIG. 4 illustrates a plan view microelectronic assembly 400, in accordance with at least one example of the present disclosure. Microelectronic assembly 400 includes package 402 and thermal assembly 404. Package 402 may include substrate 406, component 408, component 414, and component 416. Thermal assembly may include heat spreader 428, slug 434, and slug 436. Heat spreader 428 may include opening 444 and opening 446.

Microelectronic assembly 400 may be similar to microelectronic assemblies 100 and 300 discussed above with respect to FIGS. 1-2B and 3, respectively, except that FIG. 4 shows how microelectronic assembly 400 may include only two slugs, slug 434 and 436, which may be thermally coupled to components 414 and 416, respectively, while component 408 may be thermally coupled to heat spreader 428.

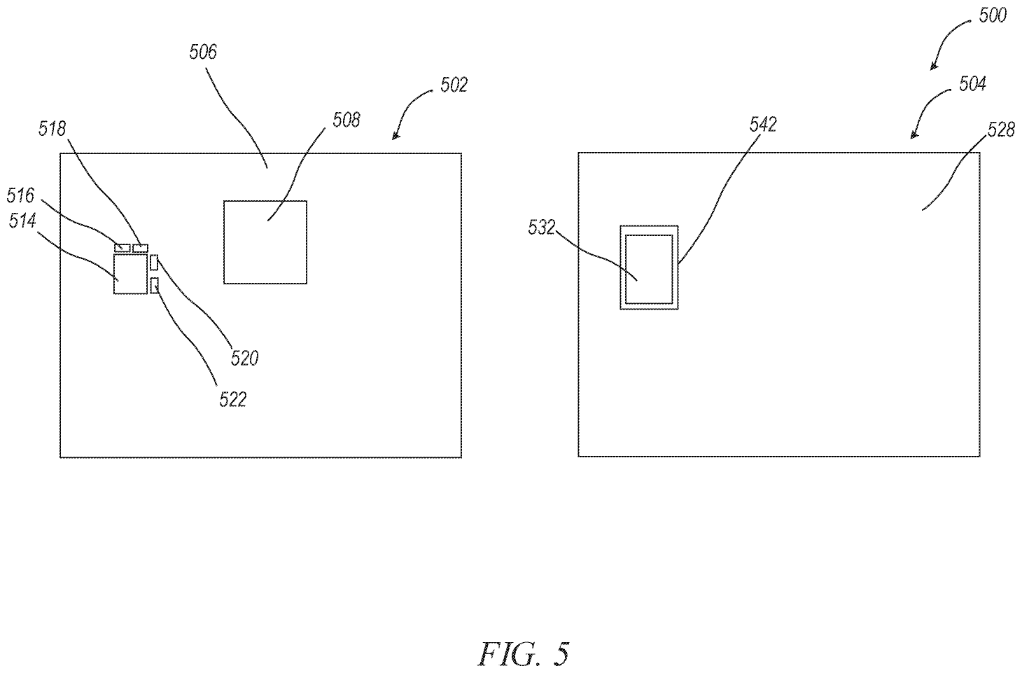

FIG. 5 illustrates a plan view microelectronic assembly 500, in accordance with at least one example of the present disclosure. Microelectronic assembly 500 includes package 502 and thermal assembly 504. Package 502 may include substrate 506, and components 508, 514, 516, 518, 520, and 522. Thermal assembly may include heat spreader 528, and slug 532. Heat spreader 528 may include opening 542.

Microelectronic assembly 500 may be similar to microelectronic assemblies 100, 300, and 400 discussed above with respect to FIGS. 1-2B, 3, and 4, respectively, except that FIG. 5 shows how microelectronic assembly 500 may include only one slug 532, which may be thermally coupled to all of components 514, 516, 518, 520, and 522, while component 508 may be thermally coupled to heat spreader 528. In this example, a single slug and a single opening may be used for multiple components, which may save manufacturing time and BOM cost. This example may also be beneficial, where, as shown in FIG. 5, components 516-520 are small and would require relatively small individual slugs, which may be susceptible to inconsistent thermal coupling to a heatsink. As a solution, a single slug, 532 is thermally coupled to all of components 514, 516, 518, 520, and 522, and may provide a consistent thermal pathway to a heatsink.

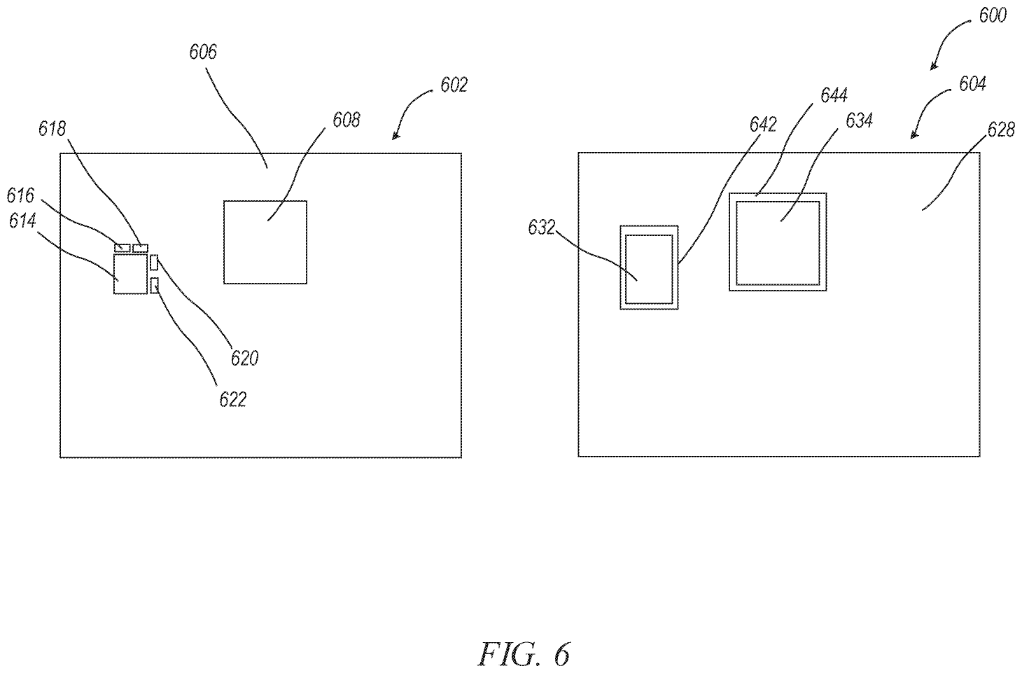

FIG. 6 illustrates a plan view microelectronic assembly 600, in accordance with at least one example of the present disclosure. Microelectronic assembly 600 includes package 602 and thermal assembly 604. Package 602 may include substrate 606, and components 608, 614, 616, 618, 620, and 622. Thermal assembly may include heat spreader 628, slug 632, and slug 634. Heat spreader 628 may include opening 542 and opening 544.

Microelectronic assembly 600 may be similar to microelectronic assemblies 100, 300, 400, and 500 discussed above with respect to FIGS. 1-2B, 3, 4, and 5 respectively, except that FIG. 6 shows how microelectronic assembly 600 may include dies that do not thermally couple to heat spreader 628. In this example, a single slug and a single opening may be used for multiple components, and a separate slug may be used for another component.

In some of these examples, slug 632 may be thermally coupled to all of components 614, 616, 618, 620, and 622, while component 608 may be thermally coupled to slug 634. In these examples, slug 634 can be optimized for thermal performance of component 608 while slug 632 can be selected to thermally couple to components 614, 616, 618, 620, and 622 to reduce cost. This can allow for optimization or selection of slugs for performance based on individual component needs, while reducing the number of slugs required, which can provide a balance of efficiency with manufacturing time and BOM cost.

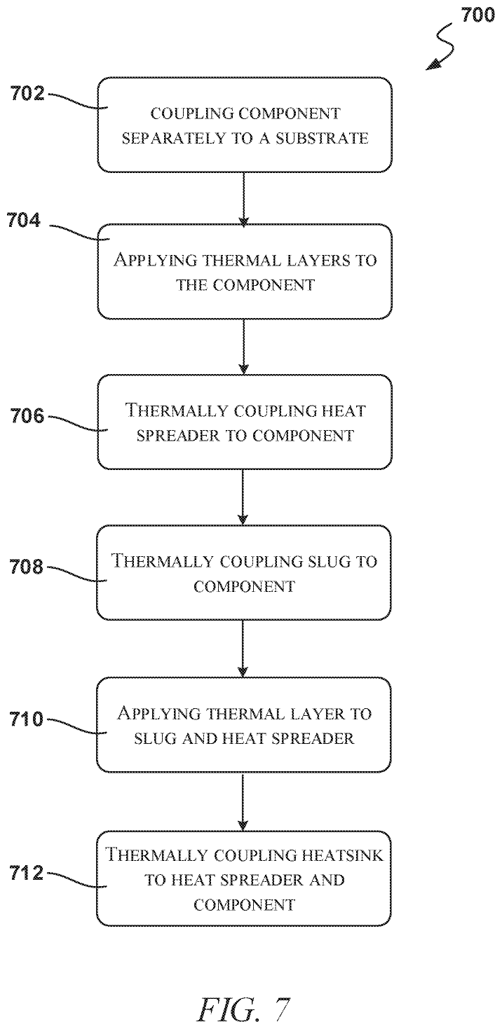

FIG. 7 illustrates a flow chart of method 700 in accordance with at least one example of the present disclosure. The operations or operations of method 700 are illustrated in a particular order for convenience and clarity. Many of the discussed operations may be performed in a different sequence or in parallel without materially impacting other operations. Method 700, as discussed, includes operations performed by multiple different actors, devices, and/or systems. It is understood that subsets of the operations discussed in method 700 attributable to a single actor, device, or system could be considered a separate standalone process or method. Method 700 may be an examples of operations or procedures performed by microelectronic assemblies or systems, such as microelectronic system 100 of FIGS. 1-2B.

At operation 702 a first and a second component, such as components 110 and 126 of FIGS. 1-2B, may be separately coupled to a substrate, such as substrate 106. At operation 704, a first thermal layer may be applied layer to the first component and a second thermal layer may be applied to the second component. For example, TIM layer 152 may be applied to component 110 and TIM layer 154 may be applied to component 126.

At operation 706, a heat spreader may be thermally coupled to the first component, where the first thermal layer is disposed between the heat spreader and the first component, such that the heat spreader contacts with the substrate. For example, heat spreader 128 may bet thermally coupled to component 110 via TIM layer 152. Heat spreader 128 may be in contact with substrate 106 via legs 128L. At operation 708, a slug may be thermally coupled to the second component, where the second thermal layer disposed between the slug and the second component. For example, slug 138 may be thermally coupled to component 126 by TIM layer 154.

At operation 710, a third thermal layer may be applied to the slug and to the heat spreader. For example, TIM layer 156 may be applied to slug 138 and to heat spreader 128. At operation 712, a heatsink may be thermally coupled to the heat spreader and the slug, where the third thermal layer is disposed between the heatsink and the heat spreader and disposed between the heatsink and the slug. For example, heatsink 162 may be thermally coupled to heat spreader 128 and to slug 138 by TIM layer 156, as shown in FIG. 2A.

In another example, a third component may be coupled to the substrate, and a fourth thermal layer may be applied to the third component, such that a second slug may be thermally coupled to the third component, where the fourth thermal layer is disposed between the second slug and the third component.

In another example, a third component may be coupled to the substrate, and a fourth thermal layer may be applied to the third component, such that the slug may be thermally coupled to the third component, where the fourth thermal layer is disposed between the slug and the third component

In another example, a third component may be coupled to the substrate, and a fourth thermal layer may be applied to the third component, such that the heat spreader may be thermally coupled to the third component, where the fourth thermal layer is disposed between the heat spreader and the third component. In some of these examples, a sealant may be applied to the slug and the heat spreader.

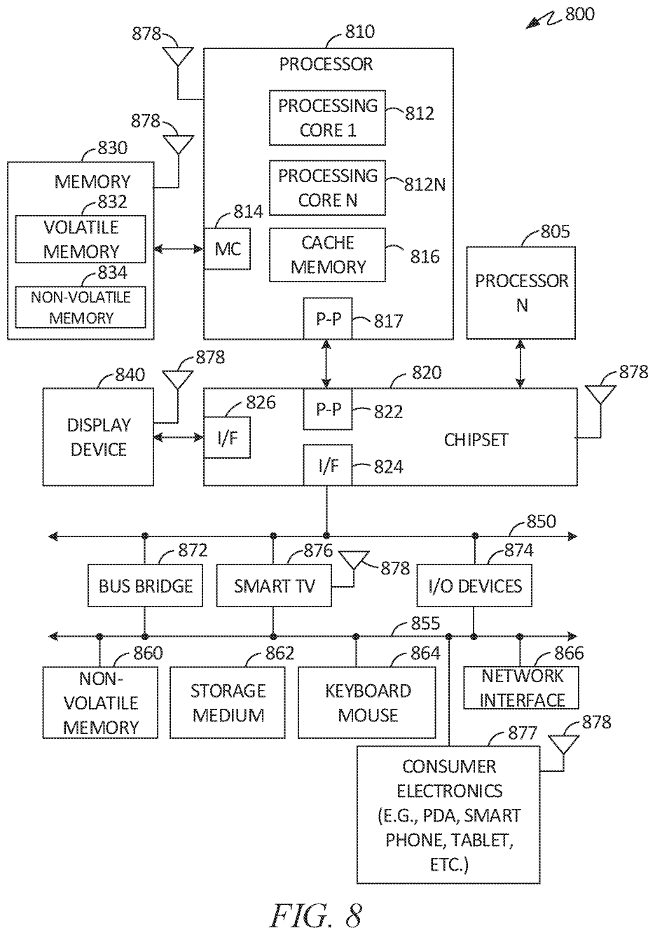

FIG. 8 illustrates system 800, in accordance with at least one example of the present disclosure, including the microelectronic devices, systems, and methods described above. FIG. 8 is included to show an example of a higher level device application for the microelectronic devices, systems, and methods described above. In one embodiment, system 800 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 800 is a system on a chip (SOC) system.

In one embodiment, processor 810 has one or more processor cores 812 and 812N, where 812N represents the Nth processor core inside processor 810 where N is a positive integer. In one embodiment, system 800 includes multiple processors including 810 and 805, where processor 805 has logic similar or identical to the logic of processor 810. In some embodiments, processing core 812 includes, but is not limited to, pre-fetch logic to fetch instructions, decode logic to decode the instructions, execution logic to execute instructions and the like. In some embodiments, processor 810 has a cache memory 816 to cache instructions and/or data for system 800. Cache memory 816 may be organized into a hierarchal structure including one or more levels of cache memory.

In some embodiments, processor 810 includes a memory controller 814, which is operable to perform functions that enable the processor 810 to access and communicate with memory 830 that includes a volatile memory 832 and/or a non-volatile memory 834. In some embodiments, processor 810 is coupled with memory 830 and chipset 820. Processor 810 may also be coupled to a wireless antenna 878 to communicate with any device configured to transmit and/or receive wireless signals. In one embodiment, an interface for wireless antenna 878 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 832 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 834 includes, but is not limited to, flash memory, phase change memory (PCM), read-only memory (ROM), electrically erasable programmable read-only memory (EEPROM), or any other type of non-volatile memory device.

Memory 830 stores information and instructions to be executed by processor 810. In one embodiment, memory 830 may also store temporary variables or other intermediate information while processor 810 is executing instructions. In the illustrated embodiment, chipset 820 connects with processor 810 via Point-to-Point (PtP or P-P) interfaces 817 and 822. Chipset 820 enables processor 810 to connect to other elements in system 800. In some embodiments of the example system, interfaces 817 and 822 operate in accordance with a PtP communication protocol such as the Intel® QuickPath Interconnect (QPI) or the like. In other embodiments, a different interconnect may be used.

In some embodiments, chipset 820 is operable to communicate with processor 810, 805N, display device 840, and other devices, including a bus bridge 872, a smart TV 876, I/O devices 874, nonvolatile memory 860, a storage medium (such as one or more mass storage devices) 862, a keyboard/mouse 864, a network interface 866, and various forms of consumer electronics 877 (such as a PDA, smart phone, tablet etc.), etc. In one embodiment, chipset 820 couples with these devices through an interface 824. Chipset 820 may also be coupled to a wireless antenna 878 to communicate with any device configured to transmit and/or receive wireless signals.

Chipset 820 connects to display device 840 via interface 826. Display 840 may be, for example, a liquid crystal display (LCD), a plasma display, cathode ray tube (CRT) display, or any other form of visual display device. In some embodiments of the example system, processor 810 and chipset 820 are merged into a single SOC. In addition, chipset 820 connects to one or more buses 850 and 855 that interconnect various system elements, such as I/O devices 874, nonvolatile memory 860, storage medium 862, a keyboard/mouse 864, and network interface 866. Buses 850 and 855 may be interconnected together via a bus bridge 872.

In one embodiment, mass storage device 862 includes, but is not limited to, a solid state drive, a hard disk drive, a universal serial bus flash memory drive, or any other form of computer data storage medium. In one embodiment, network interface 866 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home. Plug AV (HPAV), Ultra Wide Band (UWB), Bluetooth, WiMax, or any form of wireless communication protocol.

While the modules shown in FIG. 6 are depicted as separate blocks within the system 800, the functions performed by some of these blocks may be integrated within a single semiconductor circuit or may be implemented using two or more separate integrated circuits. For example, although cache memory 816 is depicted as a separate block within processor 810, cache memory 816 (or selected aspects of 816) can be incorporated into processor core 812.

### FURTHER NOTES AND EXAMPLES

To better illustrate the methods and apparatuses described herein, a non-limiting set of example embodiments are set forth below as numerically identified examples:

Example 1 is a microelectronic device comprising a substrate including a plurality of electrically conductive elements; a first component coupled to the substrate; a second component coupled to the substrate; a slug thermally coupled to the second component; a heat spreader in contact with the substrate, the heat spreader thermally coupled to the first component; and a heatsink thermally coupled to the heat spreader and the slug.

In Example 2, the subject matter of Example 1 optionally includes a third component coupled to the substrate and thermally coupled to the slug.

In Example 3, the subject matter of any one or more of Examples 1-2 optionally include a third component thermally coupled to the substrate and thermally coupled to the heat spreader.

In Example 4, the subject matter of any one or more of Examples 1-3 optionally include a third component coupled to the substrate; and a second slug thermally coupled to the third component and to the heatsink.

In Example 5, the subject matter of any one or more of Examples 1-4 optionally include a sealant between the slug and the heat spreader.

In Example 6, the subject matter of Example 5 optionally includes wherein the sealant is coupled to the first component and the substrate.

In Example 7, the subject matter of any one or more of Examples 5-6 optionally include wherein the sealant thermally couples the slug and the heat spreader.

In Example 8, the subject matter of any one or more of Examples 5-7 optionally include wherein the sealant substantially thermally isolates the slug and the heat spreader.

In Example 9, the subject matter of any one of Examples 1-8 optionally include wherein the heat spreader comprises a slug opening to receive the slug therein.

In Example 10, the subject matter of any one or more of Examples 1-9 optionally include a thermal interface layer between the heatsink and the heat spreader and between the heatsink and the slug.

In Example 11, the subject matter of any one or more of Examples 1-10 optionally include a second thermal interface layer that thermally couples the first component to the heat spreader; and a third thermal interface layer that thermally couples the second component to the slug.

In Example 12, the subject matter of any one or more of Examples 1-11 optionally include wherein the first component includes a first height from the substrate and the second component includes a second height from the substrate that is different from the first height.

Example 13 is a microelectronic system comprising: a package comprising: a substrate; a first component supported by the substrate, the first component having a first height; and a second component supported by the substrate, the second component having a second height different from the first height; a slug thermally coupled to the second component; a thermally conductive frame in contact with the substrate, the heat thermally conductive frame coupled to the first component; and a heatsink thermally coupled to the thermally conductive frame and the slug.

In Example 14, the subject matter of Example 13 optionally includes a third component coupled to the substrate and thermally coupled to the slug.

In Example 15, the subject matter of any one or more of Examples 13-14 optionally include a third component thermally coupled to the substrate and thermally coupled to the thermally conductive frame.

In Example 16, the subject matter of any one or more of Examples 13-15 optionally include a third component coupled to the substrate; and a second slug thermally coupled to the third component and to the heatsink.

In Example 17, the subject matter of any one or more of Examples 13-16 optionally include wherein the thermally conductive frame comprises a slug opening to receive the slug therein.

In Example 18, the subject matter of any one or more of Examples 1-17 optionally include a sealant between the slug and the thermally conductive frame.

In Example 19, the subject matter of Example 18 optionally includes wherein the sealant thermally couples the slug and the thermally conductive frame.

In Example 20, the subject matter of Example 19 optionally includes wherein the sealant substantially thermally isolates the slug and the thermally conductive frame.

Example 21 is a method of assembling a microelectronic system, the method comprising: coupling a first component and a second component separately to a substrate; applying a first thermal layer to the first component and a second thermal layer to the second component; coupling thermally, a heat spreader to the first component, the first thermal layer disposed between the heat spreader and the first component, such that the heat spreader contacts the substrate; coupling thermally, a slug to the second component, the second thermal layer disposed between the slug and the second component; applying a third thermal layer to the slug and the heat spreader; coupling thermally, a heatsink to the heat spreader and the slug, the third thermal layer disposed between the heatsink and the heat spreader and disposed between the heatsink and the slug.

In Example 22, the subject matter of Example 21 optionally includes coupling a third component to the substrate; applying a fourth thermal layer to the third component; and coupling thermally, a second slug to the third component, the fourth thermal layer disposed between the second slug and the third component.

In Example 23, the subject matter of any one or more of Examples 21-22 optionally include coupling a third component to the substrate; applying a fourth thermal layer to the third component; and coupling thermally, the slug to the third component, the fourth thermal layer disposed between the slug and the third component.

In Example 24, the subject matter of any one or more of Examples 21-23 optionally include coupling a third component to the substrate; applying a fourth thermal layer to the third component; and coupling thermally, the heat spreader to the third component, the fourth thermal layer disposed between the heat spreader and the third component.

In Example 25, the subject matter of any one or more of Examples 21-24 optionally include applying a sealant to the slug and the heat spreader.

In Example 26, the microelectronic devices, assemblies, or methods of any one of or an combination of Examples 1-25 is optionally configured such that all elements or options recited are available to use or select from.

The above detailed description includes references to the accompanying drawings, which form a part of the detailed description. The drawings show, by way of illustration, specific embodiments in which the disclosure may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at, least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments may be used, such as by one of ordinary skill in the art upon reviewing the above description. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments may be combined with each other in various combinations or permutations. The scope of the invention should be determined with reference to the appended claims, along with the full scope of equivalents to which such claims are entitled.

1-25. (canceled)

26. A microelectronic device comprising:
a substrate including a plurality of electrically conductive elements;
a first component coupled to the substrate;
a second component coupled to the substrate;
a slug thermally coupled to the second component;
a heat spreader in contact with the substrate, the heat spreader thermally coupled to the first component; and
a heatsink thermally coupled to the heat spreader and the slug.

27. The microelectronic device of claim 26, further comprising:
a third component coupled to the substrate and thermally coupled to the slug.

28. The microelectronic device of claim 26, further comprising:
a third component thermally coupled to the substrate and thermally coupled to the heat spreader.

29. The microelectronic device of claim 26, further comprising:
a third component coupled to the substrate; and
a second slug thermally coupled to the third component and to the heatsink.

30. The microelectronic device of claim 26, further comprising:
a sealant between the slug and the heat spreader.

31. The microelectronic device of claim 30, wherein the sealant is coupled to the first component and the substrate.

32. The microelectronic device of claim 30, wherein the sealant thermally couples the slug and the heat spreader.

33. The microelectronic device of claim 30, wherein the sealant substantially thermally isolates the slug and the heat spreader.

34. The microelectronic device of claim 26, wherein the heat spreader comprises a slug opening to receive the slug therein.

35. The microelectronic device of claim 26, further comprising:
a thermal interface layer between the heatsink and the heat spreader and between the heatsink and the slug.

36. The microelectronic device of claim 26, further comprising:
a second thermal interface layer that thermally couples the first component to the heat spreader; and
a third thermal interface layer that thermally couples the second component to the slug.

37. The microelectronic device of claim 26, wherein the first component includes a first height from the substrate and the second component includes a second height from the substrate that is different from the first height.

38. A microelectronic system comprising:
a package comprising:
a substrate;
a first component supported by the substrate, the first component having a first height; and
a second component supported by the substrate, the second component having a second height different from the first height;
a slug thermally coupled to the second component;
a thermally conductive frame in contact with the substrate, the heat thermally conductive frame coupled to the first component; and
a heatsink thermally coupled to the thermally conductive frame and the slug.

39. The microelectronic device of claim 38, further comprising:
a third component coupled to the substrate and thermally coupled to the slug.

40. The microelectronic device of claim 38, further comprising:
a third component thermally coupled to the substrate and thermally coupled to the thermally conductive frame.

41. The microelectronic device of claim 38, further comprising:
a third component coupled to the substrate; and
a second slug thermally coupled to the third component and to the heatsink.

42. A method of assembling a microelectronic system, the method comprising:
coupling a first component and a second component separately to a substrate;
applying a first thermal layer to the first component and a second thermal layer to the second component;
coupling thermally, a heat spreader to the first component, the first thermal layer disposed between the heat spreader and the first component, such that the heat spreader contacts the substrate;
coupling thermally, a slug to the second component, the second thermal layer disposed between the slug and the second component;
applying a third thermal layer to the slug and the heat spreader;
coupling thermally, a heatsink to the heat spreader and the slug, the third thermal layer disposed between the heatsink and the heat spreader and disposed between the heatsink and the slug.

43. The method of claim 42, further comprising:
coupling a third component to the substrate;
applying a fourth thermal layer to the third component; and
coupling thermally, a second slug to the third component, the fourth thermal layer disposed between the second slug and the third component.

44. The method of claim 43, further comprising:
coupling a third component to the substrate;
applying a fourth thermal layer to the third component; and
coupling thermally, the slug to the third component, the fourth thermal layer disposed between the slug and the third component.

45. The method of claim 43, further comprising:
coupling a third component to the substrate;
applying a fourth thermal layer to the third component; and
coupling thermally, the heat spreader to the third component, the fourth thermal layer disposed between the heat spreader and the third component.

46. The method of claim 43, further comprising:
applying a sealant to the slug and the heat spreader.
